(19) United States
(12) Patent Application Publication
(10) Pub. No.: US 2008/0265976 A1
(43) Pub. Date: Oct. 30, 2008

(54) COMPUTER APPARATUS AND SWITCH CONTROL METHOD THEREOF

(75) Inventor: Wan-seok KO, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/054,632

(22) Filed: Mar. 25, 2008

(30) Foreign Application Priority Data
Apr. 25, 2007 (KR) 2007-40444

(51) Int. Cl. H03K 17/28

(52) U.S. Cl. 327/398

(57) ABSTRACT

A computer apparatus includes a switch, a signal generating part which generates a signal corresponding to a position of the switch, a system part which receives the generated signal and operates, and a controller to control the signal generating part so that the signal generated in the signal generating part can be prevented from being applied to the system part for a predetermined period of time, if the switch moves from a first position to a second position.

### CROSS-REFERENCE TO RELATED APPLICATIONS

This application claims priority from Korean Patent Application No. 10-2007-0040444, filed on Apr. 25, 2007 in the Korean Intellectual Property Office, the disclosure of which is incorporated herein in its entirety by reference.

### BACKGROUND OF THE INVENTION

1. Field of the Invention

The present general inventive concept relates to a computer apparatus and a switch control method thereof, and more particularly, to a computer apparatus and a switch control method thereof which has a switch capable of a slide.

2. Description of the Related Art

In general, a computer processes data. A portable computer includes a switch performing various functions in a side part of the portable computer. For example, a slide switch is generally used to select one of a plurality of functions according to a position of the slide switch.

FIG. 1 illustrates a conventional slid switch equipped in a conventional computer 1. As illustrated in FIG. 1, the conventional computer 1 includes a switch 2 capable of sliding, and a guide part 3 to guide the switch 2.

Here, the switch 2 performs different functions according as whether the switch 2 is placed in the right or in the left. For example, as shown in FIG. 1, the switch 2 performs a hold function blocking a user's key input, and a power on/off function or a power saving mode function according to the position of the switch 2. Particularly, the switch 2 is fastened in the left by the guide part 3 when the user selects the hold function, and is placed in the right when the user selects the on/off function of the power or the power saving mode function, and then the switch 2 may be placed in a middle of the guide part 3.

However, in a case of selecting the hold function, the switch 2 moves by the user to release the hold function. However, if the switch is improperly operated, there is a problem of selecting an unwanted function. For example, if the switch is moved by the user's strong force or inadvertent improper manipulation, there is a problem of turning off the power or advancing to the power saving mode.

### SUMMARY OF THE INVENTION

The present general inventive concept provides a computer apparatus and a switch control method thereof which is capable of preventing an improper operation of a switch by a user's improper manipulation.

Additional aspects of the present general inventive concept will be set forth in part in the description which follows and, in part, will be obvious from the description, or may be learned by practice of the present general inventive concept.

The foregoing and/or other aspects of the present general inventive concept can be achieved by providing a computer apparatus including a switch including a signal generating part which generates a signal corresponding to a position of the switch, a system part which receives the generated signal and operates, a controller to control the signal generating part so that the signal generated in the signal generating part can be prevented from being applied to the system part for a predetermined period of time, if the switch moves from a first position to a second position.

The computer may further include a guide part which guides the switch to be slid.

A signal corresponding to the first position may include a signal to block a user's key input, and a signal corresponding to the second position may include one of an on/off function and a power saving mode function.

The guide part may include one of a stopper which fastens the switch to the first position and an elastic member which returns the switch from the second position to an initial position.

The foregoing and/or other aspects of the present general inventive concept can also be achieved by providing a switch control method of a computer apparatus including a switch, a signal generating part which generates a signal corresponding to a position of the switch, and a system part which receives the generated signal and operates, the switch control method including sensing whether the switch moves from a first position to a second position or not; preventing the signal generated in the signal generating part from being applied to the system part for a predetermined period of time if the switch moves to the second position.

The signal corresponding to the first position may include the signal blocking a user's key input, and the other signal corresponding to the second position may include one of an on/off function of a power and a power saving mode function.

The switch may be fastened to the first position and be returned from the second position to an initial position.

The foregoing and/or other aspects of the present general inventive concept can also be achieved by providing a computer apparatus having a switch to move between a first position and a second position, including a system part to operate a mode according to one of the first and second positions of the switch, and a controller to control the system part to stop operating the modes according to a switch moving period when the switch moves between the first position and the second position.

The foregoing and/or other aspects of the present general inventive concept can also be achieved by providing a computer apparatus having a switch, a signal generating part to generate a signal according to a position of the switch, a system part to receive the generated signal and operates a mode according to the received signal, and a controller to control the signal generating part to prevent the signal from being transmitted to the system part according to a switch moving period when the switch move between the first position and the second position.

The position of the switch comprises a first position and a second position, the signal comprises a first signal and a second signal to correspond to the first position and the second position, respectively, and the mode comprises a first mode and a second mode to correspond to the first signal and the second signal, respectively.

The controller may control the signal generating part to stop generating the first signal and the second signal according to the switching moving period.

The controller may prevent the system part to operate the first mode and the second mode during the switch moving period.

The switch may be in a stationary state between the first position and the second position, and the controller may prevent the system part to operate the first mode and the second mode during the switch moving period.

The controller may prevent the system part to operate the first mode and the second mode during a preset time shorter than the switch moving period.

The controller may include a timer to generate a preset time according to a movement of the switch from the first position and the second position, and the controller may control the signal generating part according to the present time.

The switch moving period may be a period after the present time.

The controller may control the signal generating part according to at least one of the preset time and the switch moving period.

The switching moving period may include a switch stationary period when the switch is disposed between the first position and the second position.

The switching moving period may include a switch stationary period when the switch is disposed between the first position and the second position.

The switching moving period may not include a period when the switch is in one of the first position and the second position.

The computer apparatus may further include a guide part to guide the switch to the first position and the second position, and having a guide portion formed between the first position and the second position, and the controller may control the system part when the switch is in the guide portion in the switch moving period.

The controller may control the system part to stop operating the mode.

### BRIEF DESCRIPTION OF THE DRAWINGS

These and/or other aspects and utilities of the present general inventive concept will become apparent and more readily appreciated from the following description of the embodiments, taken in conjunction with the accompanying drawings, in which:

FIG. 1 illustrates a switch of a conventional computer;

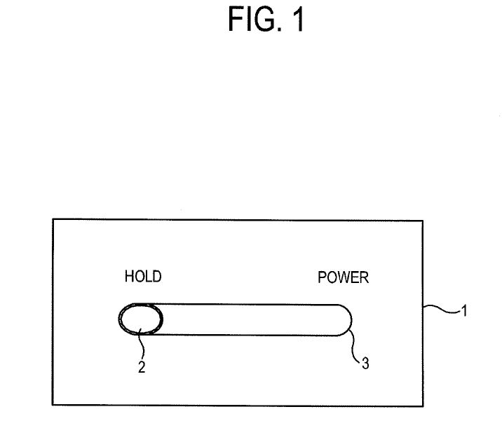

FIG. 2 is a block diagram illustrating a configuration of a computer apparatus according to an embodiment of the present general inventive concept;

FIG. 3 is a circuit diagram illustrating an operation of a controller in a computer apparatus according to an embodiment of the present general inventive concept;

FIG. 4 is a flowchart illustrating a controlling method of a switch in a computer apparatus according to an embodiment of the present general inventive concept; and

FIG. 5 is a view illustrating a relationship between a switch and a function mode in the computer apparatus of FIG. 2.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

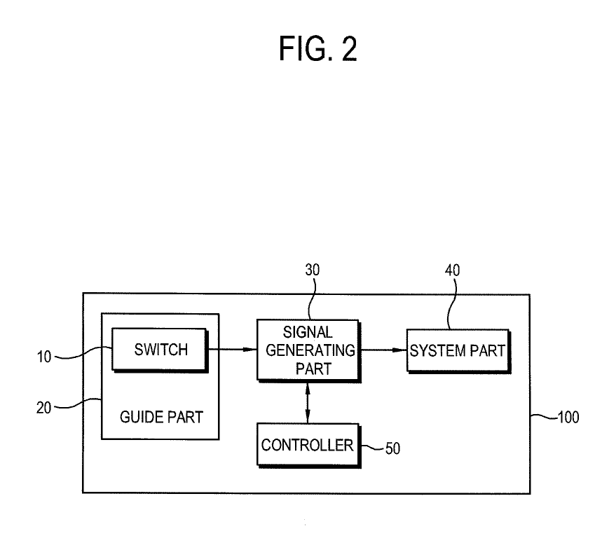

FIG. 2 is a block diagram illustrating a configuration of a computer apparatus 100 according to an embodiment of the present general inventive concept. As illustrated in FIG. 2, the computer apparatus 100 according to the present embodiment has a switch 10, a guide part 20, a signal generating part 30, and a controller 50. It is preferable but not necessary that the computer apparatus 100 according to the present general inventive concept is realized as a portable computer such as an ultra mobile personal computer (UMPC), a personal digital assistant (PDA), a portable multimedia player (PMP), etc. However, the present general inventive concept is not limited thereto, and any computer which chooses a plurality of functions with a single switch is also possible.

The switch 10 may move to a first position and a second position, and select respective functions by moving to the first position and the second position. It is preferable but not necessary the switch 10 according to the present invention is slid to the first position and the second position by the guide part 20 (to be described later).

The guide part 20 guides the switch 10 to slide along a path of the guide part between the first position and the second position. The guide part 20 according to the present embodiment may include at least one of a stopper (not illustrated) to fasten the switch 10 to the first position, and an elastic member (not shown) to return the switch 10 from the second position to an initial position.

The signal generating part 30 generates a signal corresponding to the position of the switch 10. The signal generating part 30 according to the present invention has a hold signal which performs a hold function to block a user's input to the computer 100, and a power signal to turn off the power of the computer or advance to a power saving mode.

A system part 40 receives the signal generated in the signal generating part 30 and performs a predetermined operation. The system part 40 according to the present embodiment includes at least one electronic component to perform a main function of the computer 100 when the power is supplied to the system part 40 or the computer 100 is turned on. If the computer 100 is a portable computer, the electronic component of the system part 40 may include a CPU, a RAM, a chip set, a main board, a graphic card, etc.

If the switch 10 moves from the first position to the second position, the controller 50 controls the signal generating part 30 so that the signal generated in the signal generating part 30 can be prevented from being applied to the system part 40 for a predetermined period of time. The controller according to the present embodiment may be provided as a microcomputer.

Here, the first position includes any one position corresponding to one of the plurality of optional functions selected by the switch 10 and/or corresponding to one side part of the guide part 20 as a position corresponding to the hold function to block the user's key input according to a first exemplary embodiment of the present general inventive concept. Also, the second position includes a position corresponding to the other side part of the guide part 20 as a position corresponding to the on/off function of the power or the power saving mode.

A period between a first time when the switch 10 leaves the first position to move toward the second position and a second time when the switch 10 arrives at the second position is referred to as a switch moving period. During the switch moving period, the signal generated in the signal generating part 30 can be prevented from being applied to the system part 40 for a predetermined period of time corresponding to the switch moving period. It is possible that a period between a third time when the switch 10 leaves the second position to move toward the first position and a fourth time when the switch 10 arrives at the first position can be referred to as a second switch moving period. During second switch moving period, the signal generated in the signal generating part 30 can be prevented from being applied to the system part 40 for a predetermined period of time corresponding to the second switch moving period.

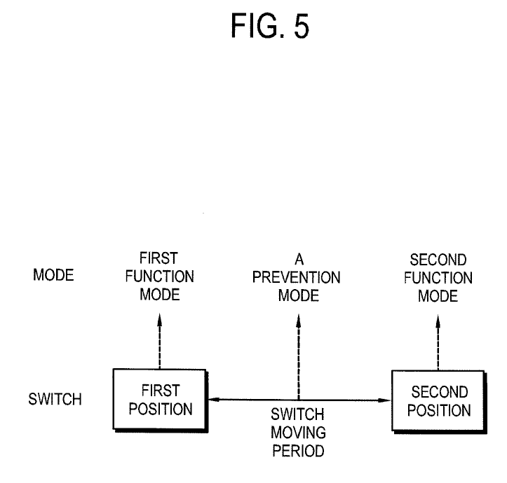

As illustrated in FIG. 5, the switch 10 moves between the first position and the second position during the switch moving period. The control part 50 controls the signal generating part 30 to generate a signal according to a first function mode when the switch 10 is in the first position, to generate another signal according to a second function mode when the switch 10 is in the second position, and to prevent a signal from being applied to the system part 40 during the switch moving period when the switch 10 moves between the first position and the second position. The first function mode may be a holding function mode, and the second function mode may be a power saving mode.

When the switch 10 is in a stationary position between the first position and the second position, the controller 50 determines that the switch 10 is in the switch moving period, and controls the signal generating part 30 and/or the system part 40 to stop operating one of the first and second function modes.

Here, the user may preset the power saving mode to be set when the switch 10 moves to the second position.

Also, a predetermined time may be preset longer than a time taken for the switch 10 to move from the first position to the second position. For example, the time may be preset as one second. It is possible that the predetermined time may be varied according to a user preference.

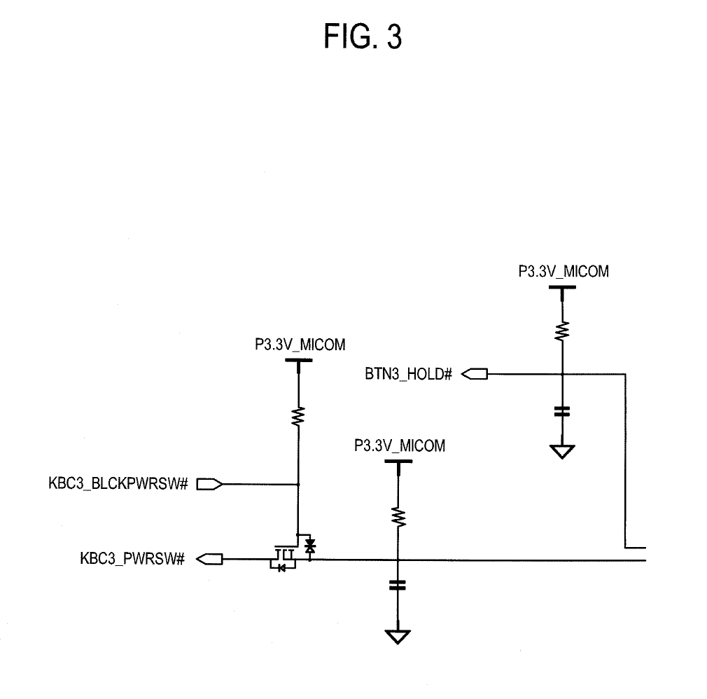

Hereinbelow, an operation of the controller 50 in the computer apparatus 100 according to the present general inventive concept will be described with reference to a circuit diagram of FIG. 3.

The controller 50 may include a power supply P3.3_MICOM, resistors, capacitors, one or more transistors, and/or one or more diodes to receive input signals from the switch 10 and to output signals to the signal generating part 30. The input signal input from the switch 10 can be received by the controller 50 through the signal generating part 30. It is possible that the signal generating part 30 generates the inputs signals according to the position of the switch 10 with respect to the guide part 20, and the controller 50 controls the signal generating part 30 to operate according to the first function mode, the second function mode, and/or a signal prevention mode corresponding to the switch moving period.

A KBC3_PWRSW# signal performs a power switch function in an active low state, a BTN_HOLD# signal performs a button hold function in an active low state and a KBC3_BLCKPWRSW# signal serves to prevent the KBC3_PWRSW# signal from being applied to the system part 40. These three signals are all transmitted from the controller 50.

When the switch 10 is placed in the first position, the BTN_HOLD# signal is in a low state and the KBC3_BLCKPWRSW# signal is in a high state.

If the switch 10 is in the second position by the user, the BTN_HOLD# signal is in a high state and the KBC3_BLCKPWRSW# signal is in a low state. When the switch 10 moves from the first position toward the second position, the controller 50 operates a predetermined timer. Also, if a preset time by the timer is determined to be elapsed, the KBC3_BLCKPWRSW# signal is initially preset to the high state.

If the KBC3_BLCKPWRSW# signal is preset to the low state, the KBC3_PWRSW# signal is not applied to the system part 40 so that the KBC3_PWRSW# signal corresponding to the on/off mode of the power or power saving mode for the predetermined period of time can be prevented from being applied to the system part 40.

When both of the BTN_HOLD# signal and the KBC3_BLCKPWRSW# signal are changed, the controller 50 determines the switch moving period, and controls the signal general part 30 to prevent a signal to be applied to the system part 40 according to the KBC3_PWRSW# signal. The preset time may be shorter than the switch moving period.

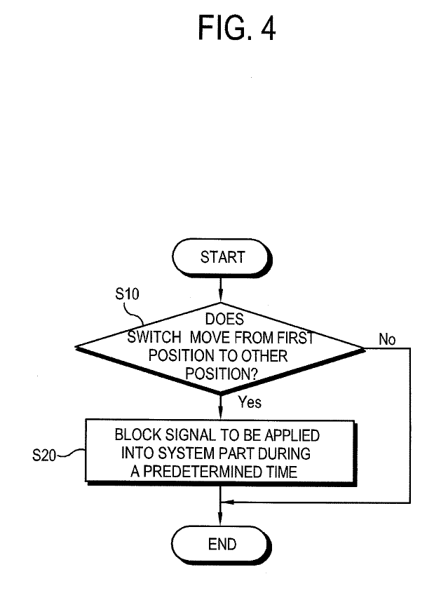

Hereinbelow, a switch control method of the computer apparatus 100 according to the present invention will be described with reference to FIG. 4.

First, the controller 50 senses whether the switch 10 moves from the first position to the second position or not (S10). Accordingly, if the switch 10 moves from the first position to the second position, the signal generated in the signal generating part 30 is prevented from being applied to the system part 40 for the predetermined period of time.

Herein, the signal corresponding to the first position may include the signal blocking the user's key input, and the signal corresponding to the second position may include one of the on/off function of the power and the power saving mode function.

As described above, an improper operation of the switch by the user's manipulation may be prevented by the computer apparatus and the switch control method thereof according to the present general inventive concept.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A computer apparatus having a switch, comprising:
a signal generating part to generate a signal corresponding to a position of the switch;
a system part to receive the generated signal and operates a mode according to the received signal;
a controller to control the signal generating part such that the signal generated in the signal generating part can be prevented from being applied to the system part for a predetermined period of time, if the switch moves from a first position to a second position.

2. The computer apparatus of claim 1, further comprising:
a guide part to guide the switch to slide.

3. The computer of claim 1, wherein the signal comprises a signal to block a user's key input according to the first position of the switch, and a signal corresponding to one of an on/off function and a power saving mode function according to the second position of the switch.

4. The computer apparatus of claim 3, wherein the guide part comprises one of a stopper which fastens the switch to the first position and an elastic member which returns the switch from the second position to an initial position.

5. A switch control method of a computer apparatus comprising a switch, a signal generating part which generates a signal corresponding to a position of the switch, and a system part which receives the generated signal and operates according to the received signal, the switch control method comprising:
sensing whether the switch moves from a first position to a second position or not;
preventing the signal generated in the signal generating part from being applied to the system part for a predetermined period of time if the switch moves to the second position.

6. The switch control method of the computer according to claim 5, wherein the signal corresponding to the first position comprises the signal blocking a user's key input, and the other signal corresponding to the second position comprises one of an on/off function of a power and a power saving mode function.

7. The switch control method of the computer according to claim 6, wherein the switch may be fastened to the first position and be returned from the second position to an initial position.

8. A computer apparatus having a switch to move between a first position and a second position, comprising:
a system part to operate a mode according to one of the first and second positions of the switch; and
a controller to control the system part to stop operating the modes according to a switch moving period when the switch moves between the first position and the second position.

9. A computer apparatus having a switch, comprising:
a signal generating part to generate a signal according to a position of the switch;
a system part to receive the generated signal and operates a mode according to the received signal; and
a controller to control the signal generating part to prevent the signal from being transmitted to the system part according to a switch moving period when the switch move between the first position and the second position.

10. The computer apparatus of claim 9, wherein:
the position of the switch comprises a first position and a second position;
the signal comprises a first signal and a second signal to correspond to the first position and the second position, respectively; and
the mode comprises a first mode and a second mode to correspond to the first signal and the second signal, respectively.

11. The computer apparatus of claim 10, wherein the controller controls the signal generating part to stop generating the first signal and the second signal according to the switching moving period.

12. The computer apparatus of claim 10, wherein the controller prevents the system part to operate the first mode and the second mode during the switch moving period.

13. The computer apparatus of claim 10, wherein the switch is in a stationary state between the first position and the second position, and the controller prevents the system part to operate the first mode and the second mode during the switch moving period.

14. The computer apparatus of claim 10, wherein the controller prevents the system part to operate the first mode and the second mode during a preset time shorter than the switch moving period.

15. The computer apparatus of claim 9, wherein the controller comprises a timer to generate a preset time according to a movement of the switch from the first position and the second position, and the controller controls the signal generating part according to the present time.

16. The computer apparatus of claim 15, wherein the switch moving period is a period after the present time.

17. The computer apparatus of claim 15, wherein the controller controls the signal generating part according to at least one of the preset time and the switch moving period.

18. The computer apparatus of claim 9, wherein the switching moving period comprises a switch stationary period when the switch is disposed between the first position and the second position.

19. The computer apparatus of claim 9, wherein the switching moving period does not include a period when the switch is in one of the first position and the second position.

20. The computer apparatus of claim 9, further comprising:
a guide part to guide the switch to the first position and the second position, and having a guide portion formed between the first position and the second position,
wherein the controller controls the system part when the switch is in the guide portion in the switch moving period.

21. The computer apparatus of claim 9, wherein the controller controls the system part to stop operating the mode.
